(19) United States
(12) Patent Application Publication
(10) Pub. No.: US 2023/0341550 A1
(43) Pub. Date: Oct. 26, 2023

(54) PROXIMITY SENSING FOR OPTICAL EMITTER SAFETY

(71) Applicant: ams Sensors Asia Pte. Ltd., Singapore (SG)

(72) Inventors: Uros Markovic, Zurich (CH); Nicola Spring, Ziegelbrücke (CH)

(21) Appl. No.: 18/001,862

(22) PCT Filed: Jun. 16, 2021
(86) PCT No.: PCT/SG2021/050351

§ 371 Date: Dec. 14, 2022

(30) Foreign Application Priority Data
Jun. 30, 2020 (GB) 2009959.4

(51) Int. Cl. G01S 17/04; G01S 7/481; H01L 31/167; H01S 5/068; H01S 5/0239

(52) U.S. Cl. CPC G01S 17/04; G01S 7/4814; H01L 31/167; H01S 5/06825; H01S 5/0239; H01S 5/183

(57) ABSTRACT

An optical emitter arrangement comprises a housing, an electrical interconnection member, and an optical emitter device mounted on the electrical interconnection member, wherein the electrical interconnection member is attached to the housing such that the optical emitter device is located within the housing. The optical emitter arrangement further comprises an optical system including an optical element for transmitting light emitted by the optical emitter device, the optical system being attached to the housing so that the optical element can receive light emitted by the optical emitter device and transmit the received light out of the housing, and the optical system further including a sensed element. The optical emitter arrangement also comprises a proximity sensor mounted on the electrical interconnection member for sensing a proximity of the sensed element. The optical emitter arrangement may enable a method of operating the optical emitter arrangement wherein the emission of light from the optical emitter arrangement is prevented in the event of a mechanical malfunction or failure of the optical emitter arrangement. The optical emitter arrangement may be used, in particular though not exclusively, in flood illuminators or projectors.

### FIELD

The present disclosure relates to an optical emitter arrangement for use, in particular though not exclusively, in flood illuminators or projectors, wherein the optical emitter arrangement is configured to prevent the optical emitter arrangement from emitting light which may cause harm to a person in the vicinity of the optical emitter arrangement in the event of a mechanical malfunction or failure of the optical emitter arrangement.

### BACKGROUND

Optical emitter arrangements are known for use in flood illuminators or for use in projectors, which optical emitter arrangements include an optical emitter device such as a VCSEL located within a housing, and an optical element fixed relative to the housing such as an optical diffuser, a lens or a lens array, so that the optical element can transmit at least a portion of the light emitted by the optical emitter device out of the housing. The optical emitter device and the optical element are held in a fixed spatial relationship relative to one another so that the emitted light which is incident on the optical element has a desired or predetermined optical field at the optical element for optimum optical performance of the optical emitter arrangement. More specifically, the optical emitter device is typically mounted on a PCB which is attached to the housing and the optical element is typically defined on, or by, an optical substrate which is also attached to the housing so that the optical emitter device and the optical element are held in the fixed spatial relationship relative to one another.

For some optical emitter arrangements, the optical emitter device may emit light which may be harmful (e.g. not eye-safe) to a person in the vicinity of the optical emitter arrangement if the emitted light is incident directly on the person without first being transmitted through the optical element. For example, the time-averaged optical power or the time-averaged optical intensity of the light emitted by the optical emitter device may be so high as to be harmful to a person if the emitted light is incident directly on the person or the peak optical power or the peak optical intensity of the light emitted by optical emitter device at any instant in time may be so high as to be harmful to a person if the emitted light is incident directly on the person. Consequently, optical emitter arrangements are known which incorporate an optical safety system, sometimes referred to as a cut-off or interlock system, which includes a controller mounted on the PCB and an electrically conductive circuit that extends from the controller to the optical substrate. In the event that the optical substrate moves relative to the housing, for example because the optical substrate becomes detached from the housing, the electrically conductive circuit is broken, the controller detects the break in the electrically conductive circuit, and the controller shuts off the supply of electrical power and/or electrical current to the optical emitter device thereby preventing the optical emitter device from emitting light which may cause harm to a person if the emitted light is incident directly on the person.

Such known optical emitter arrangements require an electrically conductive connection of some kind between the optical substrate and the housing and an electrically conductive connection of some kind between the housing and the controller to define the electrically conductive circuit between the controller and the optical substrate. However, making such electrically conductive connections may be complex and/or time-consuming. For example, it is known to form metallic tracks or traces on, or attach metallic tracks or traces to, the optical substrate; to form metallic tracks or traces on, or attach metallic tracks or traces to, the housing; and to form metallic tracks or traces on, or attach metallic tracks or traces to, the control board. However, it may be complex and/or technically challenging to make electrically conductive connections between the metallic tracks or traces of the optical substrate and the metallic tracks or traces of the housing during assembly of the optical emitter arrangement. Similarly, it may be complex and/or technically challenging to make electrically conductive connections between the metallic tracks or traces of the housing and the metallic tracks or traces of the control board during assembly of the optical emitter arrangement.

### SUMMARY

According to an aspect of the present disclosure there is provided an optical emitter arrangement, comprising:
a housing;
an electrical interconnection member;
an optical emitter device mounted on the electrical interconnection member, the electrical interconnection member being attached to the housing such that the optical emitter device is located within the housing;
an optical system including an optical element for transmitting light emitted by the optical emitter device, the optical system being attached to the housing so that the optical element can receive light emitted by the optical emitter device and transmit the received light out of the housing, and the optical system further including a sensed element; and
a proximity sensor mounted on the electrical interconnection member for sensing a proximity of the sensed element.

The proximity sensor may be configured to generate a signal which is representative of a non-contact interaction between the proximity sensor and the sensed element.

Such an optical emitter arrangement does not require any electrically conductive connections between the optical system and the housing or between the housing and the electrical interconnection member in order for the proximity sensor to generate a signal at, or on, the electrical interconnection member, which signal varies according to a spatial relationship between the optical system and the housing. Consequently, such an optical emitter arrangement may be easier and less time-consuming to manufacture than a known optical emitter arrangement which requires electrically conductive connections between an optical system and a housing and electrically conductive connections between the housing and an electrical interconnection member such as a PCB in order to generate a signal at, or on, the electrical interconnection member, which signal varies according to a spatial relationship between the optical system and the housing.

The optical emitter arrangement may comprise a controller for controlling the optical emitter device in response to the signal generated by the proximity sensor.

The controller may be configured to shut off the optical emitter device, for example by switching off a supply of electrical power and/or a supply of electrical current to the optical emitter device, in response to the signal generated by the proximity sensor.

The controller may be configured to shut off the optical emitter device, for example by switching off a supply of electrical power and/or a supply of electrical current to the optical emitter device, if the signal generated by the proximity sensor falls outside a predetermined allowable range of values. The predetermined allowable range of values may be selected so that the controller shuts off the optical emitter device if the optical system moves sufficiently relative to the housing. For example, the predetermined allowable range of values may be selected so that the controller shuts off the optical emitter device if the optical system becomes detached from the housing whilst the electrical interconnection member remains attached to the housing. Similarly, the predetermined allowable range of values may be selected so that the controller shuts off the optical emitter device if the electrical interconnection member moves sufficiently relative to the housing. For example, the predetermined allowable range of values may be selected so that the controller shuts off the optical emitter device if the electrical interconnection member becomes detached from the housing whilst the optical system remains attached to the housing. Accordingly, such an optical emitter arrangement effectively incorporates an optical safety system which may help to prevent the optical emitter arrangement from emitting light which may cause harm to a person in the vicinity of the optical emitter arrangement in the event of a mechanical malfunction or failure of the optical emitter arrangement.

The controller may be mounted on the electrical interconnection member.

The electrical interconnection member may comprise a control board or a printed circuit board (PCB).

The optical emitter device and the proximity sensor may have a predetermined spatial relationship relative to one another.

The optical emitter device and the proximity sensor may be located adjacent to one another on the electrical interconnection member.

The optical element and the sensed element may have a predetermined spatial relationship relative to one another.

The optical system may comprise an optical substrate, wherein the optical element is defined by, or on, the optical substrate. The sensed element may be defined on, or be attached to, the optical substrate. The optical substrate may be attached to the housing.

The optical element may be monolithically integrated with, or defined by a surface of, the optical substrate.

The optical element may be defined in, or formed from, a material which is formed, or deposited, on the optical substrate.

The sensed element may be defined in, or formed from, a material which is formed, or deposited, on the optical substrate.

The optical element and the sensed element may be located on the optical substrate adjacent to one another.

The optical element and the sensed element may at least partially overlap.

At least part of the sensed element may be formed or deposited on at least part of the optical element. Such an arrangement would allow a change or failure of the optical element to be sensed by the proximity sensor even if the optical substrate does not change or fail e.g. even if the optical substrate does not become detached from the housing.

At least part of the optical element may be formed or deposited on at least part of the sensed element. Such an arrangement would allow a change or failure of the optical element to be sensed by the proximity sensor even if the optical substrate does not change or fail e.g. even if the optical substrate does not become detached from the housing. Such an arrangement may also be less complex or easier to manufacture than the arrangement wherein at least part of the sensed element is formed or deposited on at least part of the optical element.

The housing may define a first opening and a second opening opposite the first opening, wherein the electrical interconnection member covers one of the first and second openings, and the optical substrate covers the other one of the first and second openings.

The sensed element may comprise, or be formed from, a magnetic material and the proximity sensor may comprise a magnetic field sensor.

The proximity sensor may comprise a Hall effect sensor.

The proximity sensor may comprise a photodetector such as a photodiode and the sensed element may be at least partially reflective, wherein the optical emitter device, the photodetector and the sensed element are arranged so that a portion of the light emitted by the optical emitter device is reflected from the sensed element and detected by the photodetector. The light which is reflected by the sensed element and which is detected by the photodetector may be representative of a state or configuration of an area of the optical substrate on which the sensed element is formed or deposited. For example, the light which is reflected by the sensed element and which is detected by the photodetector may be representative of a stress and/or a strain in the area of the optical substrate on which the sensed element is formed or deposited. The light which is reflected by the sensed element and which is detected by the photodetector may be representative of a fault or a defect in the area of the optical substrate on which the sensed element is formed or deposited such as a crack in the area of the optical substrate on which the sensed element is formed or deposited.

The sensed element may comprise, or be formed of, at least partially reflective material. One or more apertures may be defined in the at least partially reflective material. The one or more apertures may be aligned with the optical emitter device. The one or more apertures may allow light emitted by the optical emitter device to pass through the optical element.

The light which is reflected by the sensed element and which is detected by the photodetector may be representative of an environment within the housing. For example, the light which is reflected by the sensed element and which is detected by the photodetector may be representative of at least one of a pressure, a temperature, and a moisture level, of the environment within the housing.

The sensed element may define one or more non-contiguous areas of at least partially reflective material.

The light which is reflected by the one or more non-contiguous areas of the at least partially reflective material and which is detected by the photodetector may be representative of a state or configuration of an area of the optical substrate on which the one or more non-contiguous areas of the at least partially reflective material are defined. For example, the light which is reflected by the one or more non-contiguous areas of the at least partially reflective material and which is detected by the photodetector may be representative of a stress and/or a strain in the optical substrate. The light which is reflected by the one or more non-contiguous areas of the at least partially reflective material and which is detected by the photodetector may be representative of a fault or a defect in the optical substrate such as a crack in the optical substrate.

The one or more non-contiguous areas of the at least partially reflective material may be aligned with the optical emitter device. The light which is reflected by the one or more non-contiguous areas of the at least partially reflective material and which is detected by the photodetector may be representative of a state or configuration of the optical element. For example, the light which is reflected by the one or more non-contiguous areas of the at least partially reflective material and which is detected by the photodetector may be representative of a stress and/or a strain in the optical element. The light which is reflected by the one or more non-contiguous areas of the at least partially reflective material and which is detected by the photodetector may be representative of a fault or a defect in the optical element such as a crack in the optical element.

The light which is reflected by the one or more non-contiguous areas of the at least partially reflective material and which is detected by the photodetector may be representative of the environment within the housing. For example, the light which is reflected by the one or more non-contiguous areas of the at least partially reflective material and which is detected by the photodetector may be representative of at least one of a pressure, a temperature, and a moisture level, of the environment within the housing.

The proximity sensor may comprise one or more sensing electrodes and the sensed element may comprise one or more sensed electrodes, wherein the one or more sensing electrodes are separated from the one or more sensed electrodes by an electrical insulator and/or a dielectric material so as to define a capacitance therebetween.

The one or more sensing electrodes and the one or more sensed electrodes may be electrically conductive, for example metallic.

The one or more sensing electrodes may comprise one or more capacitance sensing cells and the one or more sensed electrodes may comprise a floating electrode.

The optical emitter device may comprise a light emitting diode (LED).

The optical emitter device may comprise a laser diode such as a vertical cavity surface emitting laser (VCSEL) diode.

The optical element may comprise an optical diffuser.

The optical element may be configured to spatially modulate the light emitted by the optical emitter device.

The optical element may be configured to spatially modulate the amplitude and/or phase of the light emitted by the optical emitter device.

The optical element may be refractive.

The optical element may comprise a lens.

The optical element may comprise a plurality of lenses.

The optical element may comprise a microlens array.

The optical element may be diffractive.

The optical element may comprise a diffraction grating.

The optical substrate may be partially reflective.

The optical substrate may comprise one or more reflective portions or features and one or more transmissive portions or features.

According to an aspect of the present disclosure there is provided an illuminator such as a flood illuminator comprising any of the optical emitter arrangements described above.

According to an aspect of the present disclosure there is provided a projector comprising any of the optical emitter arrangements described above.

It should be understood that any one or more of the features of any one of the foregoing aspects of the present disclosure may be combined with any one or more of the features of any of the other foregoing aspects of the present disclosure.

### BRIEF DESCRIPTION OF THE DRAWINGS

Optical emitter arrangements will now be described by way of non-limiting example only with reference to the accompanying drawings of which:

FIG. 1 is a schematic cross-sectional view of a first optical emitter arrangement including a sensed element and a proximity sensor for sensing the proximity of the sensed element;

FIG. 2 is a schematic cross-sectional view of a second optical emitter arrangement including a sensed element and a proximity sensor for sensing the proximity of the sensed element;

FIG. 3 is a schematic cross-sectional view of a third optical emitter arrangement including a sensed element and a proximity sensor for sensing the proximity of the sensed element;

FIG. 4 is a schematic cross-sectional view of a fourth optical emitter arrangement including a sensed element and a proximity sensor for sensing the proximity of the sensed element;

FIG. 5 is a schematic cross-sectional view of a fifth optical emitter arrangement including a sensed element and a proximity sensor for sensing the proximity of the sensed element;

FIG. 6A is a schematic cross-sectional view of a sixth optical emitter arrangement including a sensed element and a proximity sensor for sensing the proximity of the sensed element;

FIG. 6B is a schematic plan view of capacitive sensing cells of the proximity sensor of the sixth optical emitter arrangement of FIG. 6A; and

FIG. 6C is a schematic view of an underside of a floating electrode of the sensed element of the sixth optical emitter arrangement of FIG. 6A.

### DETAILED DESCRIPTION OF THE DRAWINGS

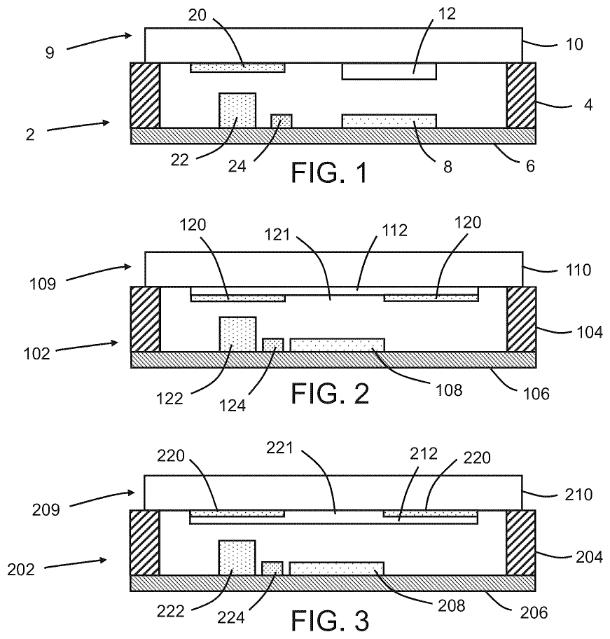

Referring initially to FIG. 1, there is shown an optical emitter arrangement generally designated 2 including a housing 4, an electrical interconnection member in the form of a printed circuit board (PCB) 6, and an optical emitter device in the form of a vertical-cavity surface emitting laser (VCSEL) 8 mounted on the PCB 6. The PCB 6 is attached to the housing 4 such that the VCSEL 8 is located within the housing 4. The optical emitter arrangement further includes an optical system 9 which includes an optical substrate 10 and an optical element in the form of an optical diffuser 12 defined on an underside of the optical substrate 10. The optical substrate 10 is attached to the housing 4 with the underside of the optical substrate 10 disposed towards the VCSEL 8. The diffuser 12 is aligned relative to the VCSEL 8 so that the diffuser 12 can transmit light emitted by the VCSEL 8 out of the housing 4. The optical system 9 further includes a sensed element in the form of a magnetic element 20 defined on the underside of the optical substrate 10 adjacent to the diffuser 12. The magnetic element may comprise a patterned layer of ferromagnetic material such as nickel. The layer of ferromagnetic material may, for example, be 50-60 μm thick. The layer of ferromagnetic material may be deposited or formed on the underside of the optical substrate 10 by evaporation or pulse sputtering. The optical emitter arrangement further includes a proximity sensor in the form of a Hall effect sensor 22 mounted on the PCB 6 in general alignment with the magnetic element 20 for sensing a proximity of the magnetic element 20. The Hall effect sensor 22 is configured to generate a signal which is representative of a magnetic field between the Hall effect sensor 22 and the magnetic element 20.

Such an optical emitter arrangement 2 does not require any electrically conductive connections between the optical system 9 and the housing 4 or between the housing 4 and the PCB 6 in order for the Hall effect sensor 22 to generate a signal at, or on, the PCB 6, which signal varies according to a spatial relationship between the optical system 9 and the housing 4. Consequently, such an optical emitter arrangement 2 may be easier and less time-consuming to manufacture than a known optical emitter arrangement which requires electrically conductive connections between an optical system and a housing and electrically conductive connections between the housing and an electrical interconnection member such as a PCB in order to generate a signal at, or on, the PCB, which signal varies according to a spatial relationship between the optical system and the housing.

The optical emitter arrangement 2 further includes a controller 24 mounted on the PCB 6. The controller 24 is configured to receive the signal generated by the Hall effect sensor 22 and to control the VCSEL 8 in response to the signal generated by the Hall effect sensor 22. Specifically, the controller 24 is configured to shut off the VCSEL 8, for example by switching off a supply of electrical power and/or a supply of electrical current to the VCSEL 8, in response to the signal generated by the Hall effect sensor 22. Specifically, the controller 24 is configured to shut off the VCSEL 8, for example by switching off a supply of electrical power and/or a supply of electrical current to the VCSEL 8, if the signal generated by the Hall effect sensor 22 falls outside a predetermined allowable range of values. The predetermined allowable range of values may be selected so that the controller 24 shuts off the VCSEL 8 if the optical system 9 moves sufficiently relative to the housing 4. For example, the predetermined allowable range of values may be selected so that the controller 24 shuts off the VCSEL 8 if the optical system 9 becomes detached from the housing 4 whilst the PCB 6 remains attached to the housing 4. Similarly, the predetermined allowable range of values may be selected so that the controller 24 shuts off the VCSEL 8 if the PCB 6 moves sufficiently relative to the housing 4. For example, the predetermined allowable range of values may be selected so that the controller 24 shuts off the VCSEL 8 if the PCB 6 becomes detached from the housing 4 whilst the optical system 9 remains attached to the housing 4. Accordingly, such an optical emitter arrangement 2 effectively incorporates an optical safety system which may help to prevent the optical emitter arrangement 2 from emitting light which may cause harm to a person in the vicinity of the optical emitter arrangement 2 in the event of a mechanical malfunction or failure of the optical emitter arrangement 2.

If a calibration is required, the signal generated by the Hall effect sensor 22 can be measured before attaching the optical system 9 to the housing 4. If the optical system 9 later fails or becomes damaged, for example the optical substrate 10 fails or becomes damaged or detached from the housing 4, the signal generated by the Hall effect sensor 22 changes and the controller 24 shuts off the VCSEL 8.

FIG. 2 shows a second optical emitter arrangement generally designated 102 including a housing 104, an electrical interconnection member in the form of a printed circuit board (PCB) 106, and an optical emitter device in the form of a vertical-cavity surface emitting laser (VCSEL) 108 mounted on the PCB 106. The PCB 106 is attached to the housing 104 such that the VCSEL 108 is located within the housing 104. The optical emitter arrangement 102 further includes an optical system 109 which includes an optical substrate 110 and an optical element in the form of an optical diffuser 112 defined on an underside of the optical substrate 110. The optical substrate 110 is attached to the housing 104 with the underside of the optical substrate 110 disposed towards the VCSEL 108. The optical system 109 further includes a sensed element in the form of a magnetic element 120. Unlike the optical emitter arrangement 2 of FIG. 1, in the optical emitter arrangement 102 of FIG. 2, the magnetic element 120 is defined on the diffuser 112. The magnetic element 120 may comprise a patterned layer of ferromagnetic material such as nickel. The layer of ferromagnetic material may, for example, be 50-60 μm thick. The layer of ferromagnetic material may be deposited or formed on the diffuser 112 by evaporation or pulse sputtering. Moreover, the magnetic element 120 defines an aperture 121. The optical substrate 110 is aligned relative to the housing 104 so that the aperture 121 is aligned with the VCSEL 108 for the transmission of light from the VCSEL 108 through the diffuser 112 and out of the housing 104. The optical emitter arrangement 102 further includes a proximity sensor in the form of a Hall effect sensor 122 mounted on the PCB 106 in general alignment with the magnetic element 120 for sensing a proximity of the magnetic element 120. The Hall effect sensor 122 is configured to generate a signal which is representative of a magnetic field between the Hall effect sensor 122 and the magnetic element 120. The optical emitter arrangement 102 further includes a controller 124 mounted on the PCB 106. The controller 124 is configured to receive the signal generated by the Hall effect sensor 122 and to control the VCSEL 108 in response to the signal generated by the Hall effect sensor 122.

One of ordinary skill in the art will understand that the optical emitter arrangement 102 of FIG. 2 may be advantageous because the signal generated by the Hall effect sensor 122 may not only vary if the optical substrate 110 fails or becomes damaged or detached from the housing 104, but the signal generated by the Hall effect sensor 122 may also vary if the portion of the diffuser 112 between the magnetic element 120 and the optical substrate 110 fails or becomes damaged or detached from the optical substrate 110, even if the optical substrate 110 does not fail or become damaged or detached from the housing 104.

Moreover, the signal generated by the Hall effect sensor 122 is dependent on the distance between the Hall effect sensor 122 and the magnetic element 120 which is, in turn, dependent on a thickness of the portion of the diffuser 112 located between the Hall effect sensor 122 and the magnetic element 120. Furthermore, the thickness of the portion of the diffuser 112 located between the Hall effect sensor 122 and the magnetic element 120 may expand or contract due to any changes in the environment within the housing 104 e.g. due to any changes in at least one of the temperature, pressure and moisture of the environment within the housing 104. Consequently, the signal generated by the Hall effect sensor 122 may be representative of the environment within the housing 104. In addition, the controller 124 may be configured to monitor the signal generated by the Hall effect sensor 122 and adjust and/or shut off the supply of electrical power and/or the supply of electrical current to the VCSEL 108 in response to any changes in the signal generated by the Hall effect sensor 122 arising as a consequence of any changes in the environment within the housing 104.

FIG. 3 shows a third optical emitter arrangement generally designated 202 including a housing 204, an electrical interconnection member in the form of a printed circuit board (PCB) 206, and an optical emitter device in the form of a vertical-cavity surface emitting laser (VCSEL) 208 mounted on the PCB 206. The PCB 206 is attached to the housing 204 such that the VCSEL 208 is located within the housing 204. The optical emitter arrangement 202 further includes an optical system 209 which includes an optical substrate 210 and an optical element in the form of an optical diffuser 212 attached to an underside of the optical substrate 210. The optical substrate 210 is attached to the housing 204 with the underside of the optical substrate 210 disposed towards the VCSEL 208. The optical system 209 further includes a sensed element in the form of a magnetic element 220 defined on an underside of the optical substrate 210. The magnetic element 220 may comprise a patterned layer of ferromagnetic material such as nickel. The layer of ferromagnetic material may, for example, be 50-60 μm thick. The layer of ferromagnetic material may be deposited or formed on the underside of the optical substrate 210 by evaporation or pulse sputtering. The magnetic element 220 defines an aperture 221. The optical substrate 210 is aligned relative to the housing 204 so that the aperture 221 is aligned with the VCSEL 208 for the transmission of light from the VCSEL 208 through the diffuser 212 and out of the housing 204. Unlike the optical emitter arrangement 102 of FIG. 2, in the optical emitter arrangement 202 of FIG. 3, the diffuser 212 is defined on the magnetic element 220. The optical emitter arrangement 202 further includes a proximity sensor in the form of a Hall effect sensor 222 mounted on the PCB 206 in general alignment with the magnetic element 220 for sensing a proximity of the magnetic element 220. The Hall effect sensor 222 is configured to generate a signal which is representative of a magnetic field between the Hall effect sensor 222 and the magnetic element 220. The optical emitter arrangement 202 further includes a controller 224 mounted on the PCB 206. The controller 224 is configured to receive the signal generated by the Hall effect sensor 222 and to control the VCSEL 208 in response to the signal generated by the Hall effect sensor 222.

One of ordinary skill in the art will understand that the optical emitter arrangement 202 of FIG. 3 may be advantageous because the signal generated by the Hall effect sensor 222 may not only vary if the optical substrate 210 fails or becomes damaged or detached from the housing 204, but the signal generated by the Hall effect sensor 222 may also vary if the portion of the diffuser 212 between the Hall effect sensor 222 and the magnetic element 220 fails or becomes damaged or detached from the optical substrate 210, even if the optical substrate 210 does not fail or become damaged or detached from the housing 204.

Moreover, forming the magnetic element 220 on the underside of the optical substrate 210 and then forming the diffuser 212 over the magnetic element 220 may also be simpler than forming the magnetic element 120 on the diffuser 112 as required for the case of the optical emitter arrangement 102 of FIG. 2.

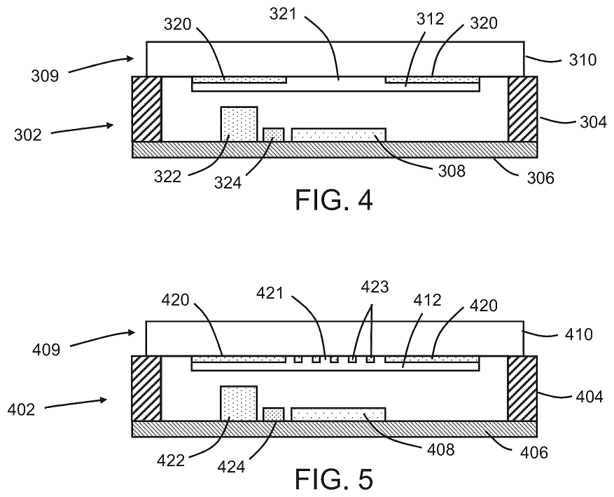

FIG. 4 shows a fourth optical emitter arrangement generally designated 302 including a housing 304, an electrical interconnection member in the form of a printed circuit board (PCB) 306, and an optical emitter device in the form of a vertical-cavity surface emitting laser (VCSEL) 308 mounted on the PCB 306. The PCB 306 is attached to the housing 304 such that the VCSEL 308 is located within the housing 304. The optical emitter arrangement 302 further includes an optical system 309 which includes an optical substrate 310 and an optical element in the form of an optical diffuser 312 attached to an underside of the optical substrate 310. The optical substrate 310 is attached to the housing 304 with the underside of the optical substrate 310 disposed towards the VCSEL 308. The optical system 309 further includes a sensed element in the form of a reflective element 320 defined on an underside of the optical substrate 310. The reflective element 320 may comprise, or be formed of, a metal such as silver, gold or aluminium. The reflective element 320 defines an aperture 321. The optical substrate 310 is aligned relative to the housing 304 so that the aperture 321 is aligned with the VCSEL 308 for the transmission of light from the VCSEL 308 through the diffuser 312 and out of the housing 304.

The diffuser 312 is defined on the reflective element 320. The optical emitter arrangement 302 further includes a proximity sensor in the form of a photodetector such as a photodiode 322 mounted on the PCB 306 for receiving light reflected from the reflective element 320. The photodiode 322 is configured to generate a signal which is representative of the light which is emitted by the VCSEL 308 and which is reflected by the reflective element 320. The optical emitter arrangement 302 further includes a controller 324 mounted on the PCB 306. The controller 324 is configured to receive the signal generated by the photodiode 322 and to control the VCSEL 308 in response to the signal generated by the photodiode 322.

One of ordinary skill in the art will understand that the optical emitter arrangement 302 of FIG. 4 may be advantageous because the signal generated by the photodiode 322 may not only vary if the optical substrate 310 fails or becomes damaged or detached from the housing 304, but the signal generated by the photodiode 322 may also vary if the portion of the diffuser 312 between the photodiode 322 and the reflective element 320 fails or becomes damaged or detached from the optical substrate 310, even if the optical substrate 310 does not fail or become damaged or detached from the housing 304.

Moreover, the signal generated by the photodiode 322 is dependent not only on the distance between the photodiode 322 and the reflective element 320, but also on the properties, including the thickness, of the portion of the diffuser 312 located between the photodiode 322 and the reflective element 320. Furthermore, the properties, including the thickness, of the portion of the diffuser 312 located between the photodiode 322 and the reflective element 320 may vary due to any changes in the environment within the housing 304 e.g. due to any changes in at least one of the temperature, pressure and moisture of the environment within the housing 304. Consequently, the signal generated by the photodiode 322 may be representative of the environment within the housing 304. In addition, the controller 324 may be configured to monitor the signal generated by the photodiode 322 and adjust and/or shut off the supply of electrical power and/or the supply of electrical current to the VCSEL 308 in response to any changes in the signal generated by the photodiode 322 arising as a consequence of any changes in the environment within the housing 304.

In addition, the signal generated by the photodiode 322 is representative of, for example proportional to, the optical power emitted by the VCSEL 308. Consequently, the controller 324 may be configured to monitor the signal generated by the photodiode 322 and adjust the supply of electrical power and/or the supply of electrical current to the VCSEL 308 to vary the optical power emitted by the VCSEL 308.

FIG. 5 shows a fifth optical emitter arrangement generally designated 402 including a housing 404, an electrical interconnection member in the form of a printed circuit board (PCB) 406, and an optical emitter device in the form of a vertical-cavity surface emitting laser (VCSEL) 408 mounted on the PCB 406. The PCB 406 is attached to the housing 404 such that the VCSEL 408 is located within the housing 404. The optical emitter arrangement 402 further includes an optical system 409 which includes an optical substrate 410 and an optical element in the form of an optical diffuser 412 attached to an underside of the optical substrate 410. The optical substrate 410 is attached to the housing 404 with the underside of the optical substrate 410 disposed towards the VCSEL 408. The optical system 409 further includes a sensed element in the form of a reflective element 420 defined on an underside of the optical substrate 410. The reflective element 420 may comprise, or be formed of, a metal such as silver, gold or aluminium. The reflective element 420 defines an aperture 421 and a plurality of non-contiguous reflective areas 423 located within the aperture 421. The optical substrate 410 is aligned relative to the housing 404 so that the aperture 421 is aligned with the VCSEL 408 for the transmission of light from the VCSEL 408 through the diffuser 412 and out of the housing 404.

The diffuser 412 is defined on the reflective element 420. The optical emitter arrangement 402 further includes a proximity sensor in the form of a photodetector such as a photodiode 422 mounted on the PCB 406 for receiving light reflected from the reflective element 420. The photodiode 422 is configured to generate a signal which is representative of the light which is emitted by the VCSEL 408 and which is reflected by the reflective element 420. The optical emitter arrangement 402 further includes a controller 424 mounted on the PCB 406. The controller 424 is configured to receive the signal generated by the photodiode 422 and to control the VCSEL 408 in response to the signal generated by the photodiode 422.

One of ordinary skill in the art will understand that the optical emitter arrangement 402 of FIG. 5 may be advantageous because the signal generated by the photodiode 422 may not only vary if the optical substrate 410 fails or becomes damaged or detached from the housing 404, but the signal generated by the photodiode 422 may also vary if the portion of the diffuser 412 between the photodiode 422 and the reflective element 420 fails or becomes damaged or detached from the optical substrate 410, even if the optical substrate 410 does not fail or become damaged or detached from the housing 404.

Moreover, the signal generated by the photodiode 422 is dependent not only on the distance between the photodiode 422 and the reflective element 420, but also on the properties, including the thickness, of the portion of the diffuser 412 located between the photodiode 422 and the reflective element 420, and on the properties, including the horizontal separation, of the non-contiguous reflective areas 423 of the reflective element 420. Furthermore, the properties, including the thickness, of the portion of the diffuser 412 located between the photodiode 422 and the reflective element 420 and the properties, including the horizontal separation, of the non-contiguous reflective areas 423 of the reflective element 420 may vary due to any changes in the environment within the housing 404 e.g. due to any changes in at least one of the temperature, pressure and moisture of the environment within the housing 404. Consequently, the signal generated by the photodiode 422 may be representative of the environment within the housing 404. In addition, the controller 424 may be configured to monitor the signal generated by the photodiode 422 and adjust and/or shut off the supply of electrical power and/or the supply of electrical current to the VCSEL 408 in response to any changes in the signal generated by the photodiode 422 arising as a consequence of any changes in the environment within the housing 404.

In addition, the signal generated by the photodiode 422 is representative of, for example proportional to, the optical power emitted by the VCSEL 408. Consequently, the controller 424 may be configured to monitor the signal generated by the photodiode 422 and adjust the supply of electrical power and/or the supply of electrical current to the VCSEL 408 to vary the optical power emitted by the VCSEL 408.

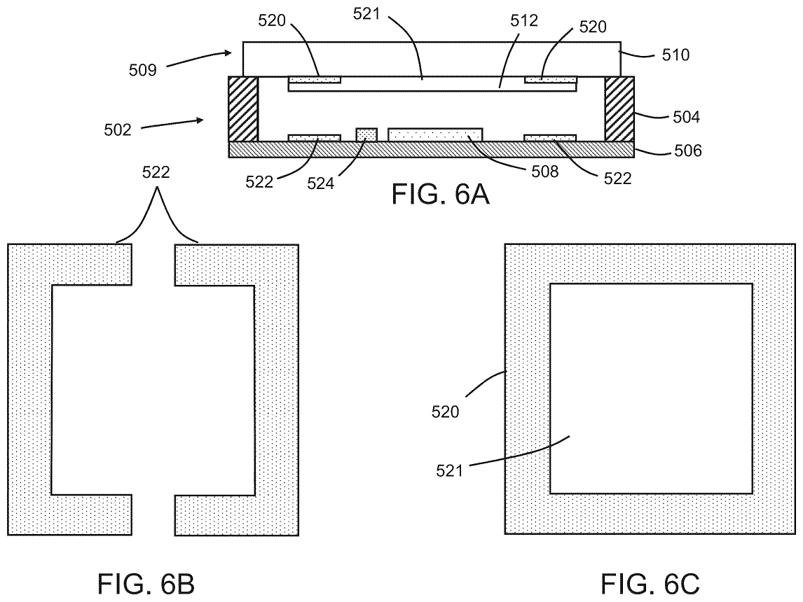

Referring now to FIG. 6A there is shown a sixth optical emitter arrangement generally designated 502 including a housing 504, an electrical interconnection member in the form of a printed circuit board (PCB) 506, and an optical emitter device in the form of a vertical-cavity surface emitting laser (VCSEL) 508 mounted on the PCB 506. The PCB 506 is attached to the housing 504 such that the VCSEL 508 is located within the housing 504. The optical emitter arrangement 502 further includes an optical system 509 which includes an optical substrate 510 and an optical element in the form of an optical diffuser 512 attached to an underside of the optical substrate 510. The optical substrate 510 is attached to the housing 504 with the underside of the optical substrate 510 disposed towards the VCSEL 508. The optical system 509 further includes a sensed element in the form of a floating electrode 520 defined on an underside of the optical substrate 510. As shown in FIG. 6C, the floating electrode 520 defines an aperture 521. The optical substrate 510 is aligned relative to the housing 504 so that the aperture 521 is aligned with the VCSEL 508 for the transmission of light from the VCSEL 508 through the diffuser 512 and out of the housing 504.

The diffuser 512 is defined on the floating electrode 520. The optical emitter arrangement 502 further includes a proximity sensor in the form of one or more capacitive sending electrodes 522 mounted on the PCB 506. The sensing electrodes 522 are shown in FIG. 6B. The sensing electrodes 522 are configured to generate a signal which is representative of the capacitance between the sensing electrodes 522 and the floating electrode 520. The optical emitter arrangement 502 further includes a controller 524 mounted on the PCB 506. The controller 524 is configured to receive the signal generated by the sensing electrodes 522 and to control the VCSEL 508 in response to the signal generated by the sensing electrodes 522.

One of ordinary skill in the art will understand that the optical emitter arrangement 502 of FIG. 6A may be advantageous because the signal generated by the sending electrodes 522 may not only vary if the optical substrate 510 fails or becomes damaged or detached from the housing 504, but the signal generated by the sending electrodes 522 may also vary if the portion of the diffuser 512 between the sending electrodes 522 and the floating electrode 520 fails or becomes damaged or detached from the optical substrate 510, even if the optical substrate 510 does not fail or become damaged or detached from the housing 504.

Moreover, the signal generated by the sending electrodes 522 is dependent not only on the distance between the sending electrodes 522 and the floating electrode 520, but also on the properties, including the thickness, of the portion of the diffuser 512 located between the sending electrodes 522 and the floating electrode 520. Furthermore, the properties, including the thickness, of the portion of the diffuser 512 located between the sending electrodes 522 and the floating electrode 520 may vary due to any changes in the environment within the housing 504 e.g. due to any changes in at least one of the temperature, pressure and moisture of the environment within the housing 504. Consequently, the signal generated by the sending electrodes 522 may be representative of the environment within the housing 504. In addition, the controller 524 may be configured to monitor the signal generated by the sending electrodes 522 and adjust and/or shut off the supply of electrical power and/or the supply of electrical current to the VCSEL 508 in response to any changes in the signal generated by the sending electrodes 522 arising as a consequence of any changes in the environment within the housing 504.

One of ordinary skill in the art will understand that various modifications are possible to the optical emitter arrangements described above. For example, rather than using a VCSEL, the optical emitter arrangements may use an optical emitter device of any kind. For example, the optical emitter arrangements may use a laser diode of a different kind or an LED.

The optical element may be configured to spatially modulate the light emitted by the optical emitter device. The optical element may be configured to spatially modulate the amplitude and/or phase of the light emitted by the optical emitter device.

The optical element may be refractive.

The optical element may comprise a lens.

The optical element may comprise a plurality of lenses.

The optical element may comprise a microlens array.

The optical element may be diffractive.

The optical element may comprise a diffraction grating.

The optical substrate may be partially transparent or translucent.

The optical substrate may comprise or be formed from glass.

In some embodiments, the optical element may be monolithically integrated with, or defined by a surface of, the optical substrate. In some embodiments, the optical element may be defined in, or formed from, a material which is formed, or deposited, on the optical substrate.

Although a PCB is used as an electrical interconnection member in all of the foregoing embodiments, any form electrical interconnection member may be used instead, for example a control board may be used instead.

Although a controller is described in all of the foregoing embodiments as being mounted on a PCB, the controller may be provided separately from the PCB whilst still being configured for communication with the optical emitter device and the proximity sensor for controlling the optical emitter device in response to the signal generated by the proximity sensor. In some embodiments, the controller may be located outside the housing.

One or both of the magnetic elements 120 and 220 may be formed from a material which is transparent to light from the VCSELs 108, 208. The use of transparent magnetic elements 120, 220 would avoid any need to define the apertures 121, 221 in the magnetic elements 120, 220 for the transmission of light from the VCSELs 108, 208.

Rather than forming the reflective elements 320, 420 on the underside of the optical substrates 310, 410 and then forming the diffusers 312, 412 on the reflective elements 320, 420 as described with reference to FIGS. 4 and 5, the diffusers 312, 412 may be formed on the underside of the optical substrates 310, 410 and the reflective elements 320, 420 may then be formed on the diffusers 312, 412.

The reflective elements 320, 420 may be highly reflective or may be only partially reflective.

Embodiments of the present disclosure can be employed in many different applications including in flood illuminators or in projectors.

Although the disclosure has been described in terms of preferred embodiments as set forth above, it should be understood that these embodiments are illustrative only and that the claims are not limited to those embodiments. Those skilled in the art will be able to make modifications and alternatives to the described embodiments in view of the disclosure which are contemplated as falling within the scope of the appended claims. Each feature disclosed or illustrated in the present specification may be incorporated in any embodiment, whether alone or in any appropriate combination with any other feature disclosed or illustrated herein. In particular, one of ordinary skill in the art will understand that one or more of the features of the embodiments of the present disclosure described above with reference to the drawings may produce effects or provide advantages when used in isolation from one or more of the other features of the embodiments of the present disclosure and that different combinations of the features are possible other than the specific combinations of the features of the embodiments of the present disclosure described above.

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Use of the term “comprising” when used in relation to a feature of an embodiment of the present disclosure does not exclude other features or steps. Use of the term “a” or “an” when used in relation to a feature of an embodiment of the present disclosure does not exclude the possibility that the embodiment may include a plurality of such features.

The use of reference signs in the claims should not be construed as limiting the scope of the claims.

### LIST OF REFERENCE NUMERALS

2 optical emitter arrangement;
4 housing;
6 PCB;
8 VCSEL;
9 optical system;
10 optical substrate;
12 optical diffuser;
20 magnetic element;
22 Hall effect sensor;
24 controller;
102 optical emitter arrangement;
104 housing;
106 PCB;
108 VCSEL;
109 optical system;
110 optical substrate;
112 optical diffuser;
120 magnetic element;
121 aperture in magnetic element 120;
122 Hall effect sensor;
124 controller;
202 optical emitter arrangement;
204 housing;
206 PCB;
208 VCSEL;
209 optical system;
210 optical substrate;
212 optical diffuser;
220 magnetic element;
221 aperture in magnetic element 220;
222 Hall effect sensor;
224 controller;
302 optical emitter arrangement;
304 housing;
306 PCB;
308 VCSEL;
309 optical system;
310 optical substrate;
312 optical diffuser;
320 reflective element;
321 aperture in reflective element 320;
322 photodiode;
324 controller;
402 optical emitter arrangement;
404 housing;
406 PCB;
408 VCSEL;
409 optical system;
410 optical substrate;
412 optical diffuser;
420 reflective element;
421 aperture in reflective element 420;
422 photodiode;
423 non-contiguous reflective areas of reflective element 420;
424 controller;
502 optical emitter arrangement;
504 housing;
506 PCB;
508 VCSEL;
509 optical system;
510 optical substrate;
512 optical diffuser;
520 floating electrode;
521 aperture in floating electrode 520;
522 sensing electrodes; and
524 controller.

1. An optical emitter arrangement, comprising:
a housing;
an electrical interconnection member;
an optical emitter device mounted on the electrical interconnection member, the electrical interconnection member being attached to the housing such that the optical emitter device is located within the housing;
an optical system including an optical element for transmitting light emitted by the optical emitter device, the optical system being attached to the housing so that the optical element can receive light emitted by the optical emitter device and transmit the received light out of the housing, and the optical system further including a sensed element; and
a proximity sensor mounted on the electrical interconnection member for sensing a proximity of the sensed element,
wherein the optical system includes an optical substrate,
wherein the optical substrate is attached to the housing,
wherein the sensed element is defined on, or is attached to, the optical substrate,
wherein the optical element is defined by, or on, the optical substrate, and
wherein at least part of the optical element is formed or deposited on at least part of the sensed element.

2. The optical emitter arrangement of claim 1, wherein the proximity sensor is configured to generate a signal which is representative of a non-contact interaction between the proximity sensor and the sensed element and the optical emitter arrangement further comprises a controller for controlling the optical emitter device in response to the signal generated by the proximity sensor.

3. The optical emitter arrangement of claim 2, wherein the controller is configured to shut off the optical emitter device, for example by switching off a supply of electrical power and/or a supply of electrical current to the optical emitter device, in response to the signal generated by the proximity sensor.

4. The optical emitter arrangement of claim 2, wherein the controller is mounted on the electrical interconnection member.

5. (canceled)

6. The optical emitter arrangement of claim 1, wherein the optical element is monolithically integrated with, or defined by a surface of, the optical substrate or the optical element is defined in, or formed from, a material which is formed, or deposited, on the optical substrate.

7. The optical emitter arrangement of claim 1, wherein the sensed element is defined in, or formed from, a material which is formed, or deposited, on the optical substrate.

8.-9. (canceled)

10. The optical emitter arrangement of claim 1, wherein the sensed element comprises, or is formed from, a magnetic material and the proximity sensor comprises a magnetic field sensor.

11. The optical emitter arrangement of claim 10, wherein the proximity sensor comprises a Hall effect sensor.

12. The optical emitter arrangement of claim 1, wherein the proximity sensor comprises a photodetector such as a photodiode and the sensed element is at least partially reflective, and wherein the optical emitter device, the photodetector and the sensed element are arranged so that a portion of the light emitted by the optical emitter device is reflected from the sensed element and detected by the photodetector.

13. The optical emitter arrangement of claim 12, wherein the sensed element comprises, or is formed of, at least partially reflective material, wherein one or more apertures are defined in the at least partially reflective material, and wherein the one or more apertures are aligned with the optical emitter device.

14. The optical emitter arrangement of claim 12, wherein the sensed element defines one or more non-contiguous areas of at least partially reflective material.

15. The optical emitter arrangement of claim 14, wherein the one or more non-contiguous areas of the at least partially reflective material are aligned with the optical emitter device.

16. The optical emitter arrangement of claim 1, wherein the proximity sensor comprises one or more sensing electrodes and the sensed element comprises one or more sensed electrodes, and wherein the one or more sensing electrodes are separated from the one or more sensed electrodes by an electrical insulator and/or a dielectric material so as to define a capacitance therebetween.

17. The optical emitter arrangement of claim 16, wherein the one or more sensing electrodes comprise one or more capacitance sensing cells and the one or more sensed electrodes comprise a floating electrode.

18. The optical emitter arrangement of claim 1, wherein the optical emitter device comprises a light emitting diode or a laser diode such as a vertical cavity surface emitting laser diode.

19. The optical emitter arrangement of claim 1, wherein at least one of:
the optical element comprises an optical diffuser;
the optical element is configured to spatially modulate the light emitted by the optical emitter device;
the optical element is configured to spatially modulate the amplitude and/or phase of the light emitted by the optical emitter device;
the optical element is refractive;
the optical element comprises a lens;
the optical element comprises a plurality of lenses;
the optical element comprises a microlens array;
the optical element is diffractive; and
the optical element comprises a diffraction grating.

20. A projector or an illuminator such as a flood illuminator, comprising the optical emitter arrangement of claim 1.
